(19) United States
(12) Patent Application Publication
(10) Pub. No.: US 2024/0407169 A1
(43) Pub. Date: Dec. 5, 2024

(54) SEMICONDUCTOR DEVICES AND MANUFACTURING METHODS THEREOF AND MEMORY SYSTEMS

(71) Applicant: Yangtze Memory Technologies Co., Ltd., Wuhan (CN)

(72) Inventors: Tingting Zhao, Wuhan (CN); Wenbo Zhang, Wuhan (CN); Sheng Peng, Wuhan (CN); Sizhe Li, Wuhan (CN); ZhiYong Lu, Wuhan (CN); Kai Yu, Wuhan (CN); Zhaohui Cheng, Wuhan (CN); Zhangyi Li, Wuhan (CN); Jing Gao, Wuhan (CN); Meng Zhang, Wuhan (CN); Kaijun Cao, Wuhan (CN); Lei Xue, Wuhan (CN); ZongLiang Huo, Wuhan (CN)

(21) Appl. No.: 18/456,467

(22) Filed: Aug. 25, 2023

(30) Foreign Application Priority Data
May 31, 2023 (CN) 202310650054.1

(51) Int. Cl. H10B 43/35; H10B 43/27

(52) U.S. Cl. CPC H10B 43/35; H10B 43/27

(57) ABSTRACT

The present application provides a semiconductor device and a manufacturing method thereof and a memory system. The manufacturing method of the semiconductor device includes: forming a dielectric layer on a stack layer, wherein memory channel structures penetrating through the stack layer along a first direction are disposed in the stack layer, and the first direction is parallel to a stacking direction of the stack layer; forming a plurality of openings penetrating through the dielectric layer along the first direction, with the rest of the dielectric layer forming top selective gate cut lines, wherein the plurality of openings are arranged as being spaced apart along a second direction, one of the top selective gate cut lines is located between two adjacent ones of the openings in the second direction, and the first direction intersects the second direction; and forming a top selective gate layer in the plurality of openings.

### CROSS-REFERENCE TO RELATED APPLICATION

This application claims priority to and the benefit of Chinese Patent Application 202310650054.1, filed on May 31, 2023, which is hereby incorporated by reference in its entirety.

### SUMMARY

### TECHNICAL FIELD

The present application relates to the technical field of semiconductors, and particularly to semiconductor devices and manufacturing methods thereof, and memory systems.

### BACKGROUND

In recent years, the development of a memory is particularly fast. The major characteristic of the memory is that it can keep stored information for a long time without power supply, and the memory has the advantages such as high integration, fast access speed, easiness in erasing and rewriting and the like. Therefore, the memory is widely applied in multiple fields, such as microcomputers, automatic control, and the like.

### BRIEF DESCRIPTION OF THE DRAWINGS

FIGS. 1A to 1E are schematic structure diagrams of a manufacturing method of a semiconductor device of some examples;

FIG. 2 is a flow diagram of a manufacturing method of a semiconductor device of some examples of the present application;

FIGS. 3A, 3B, 3D, 3E, 3F and 3H are schematic structure diagrams of processes of a manufacturing method of a semiconductor device of some examples of the present application;

FIGS. 3C, 3G, 3I and 3J are schematic structure diagrams of processes of a manufacturing method of a semiconductor device of some other examples of the present application;

FIG. 4 is a schematic structure diagram of a memory of some examples of the present application;

FIG. 5 is a block diagram of a memory system of some examples of the present application;

FIG. 6 is a block diagram of a memory system of some other examples of the present application; and

FIG. 7 is a block diagram of an electronic apparatus of some examples of the present application.

Reference numerals are as follows:

z: first direction; x: second direction; y: third direction;

10, 20: semiconductor layer; 1: semiconductor structure;

11, 21: stack layer; 21a: lower stack layer; 21b: upper stack layer; 111, 211: gate dielectric layer; 2111: first gate dielectric layer; 2112: second gate dielectric layer; 112, 212: sacrificial layer; 2121: first sacrificial layer; 2122: second sacrificial layer; 21c: block memory area; 21d: finger memory area;

14a, 22: dielectric layer; 22a: opening; 22b: groove; 141, 221: top selective gate cut line; 142, 222: gate line slit top insulation portion;

12, 23: memory channel structure; 231: blocking layer; 232: charge trapping layer; 233: tunneling layer; 234: channel layer; 235: channel filling layer; 236: channel plug;

241: first isolation layer; 242: second isolation layer; 243: third isolation layer; 243a: isolation layer opening; 244: fourth isolation layer; 245: fifth isolation layer;

13, 25: initial top selective gate layer; 13a: top selective gate cut; 13b: gate line slit top insulation portion opening; 131, 251: top selective gate layer; 2511: top selective gate; 15, 26: top selective channel structure;

27a: gate line slit; 16, 27: gate line slit structure;

28: memory stack layer; 113, 281: gate layer.

200: semiconductor device; 300: memory; 301: memory array; 302: peripheral circuit; 400: controller; 500: memory system; 600: host; 700: electronic apparatus.

### DETAILED DESCRIPTION

As the manufacturing process of memory becomes more and more difficult, how to fabricate the memory to improve its performance has become an urgent problem.

The technical solutions in examples of the present application will be described below clearly and completely in conjunction with the drawings in the examples of the present application. The examples described are only part of, but not all of, the examples of the present application. All other examples obtained by those skilled in the art based on the examples in the present application without creative work shall fall in the scope of protection of the present application.

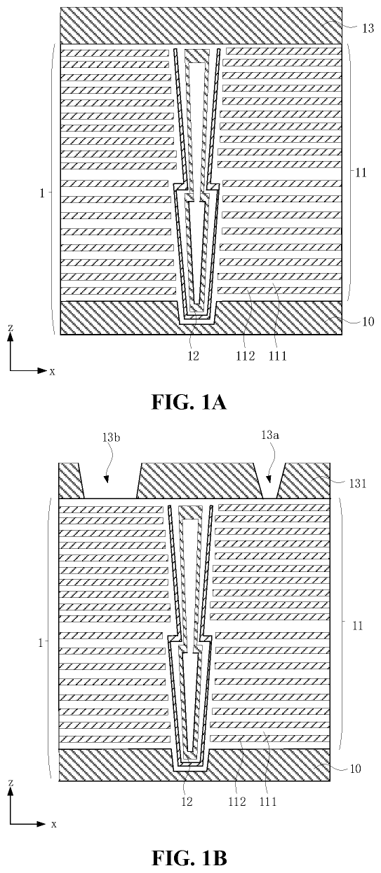

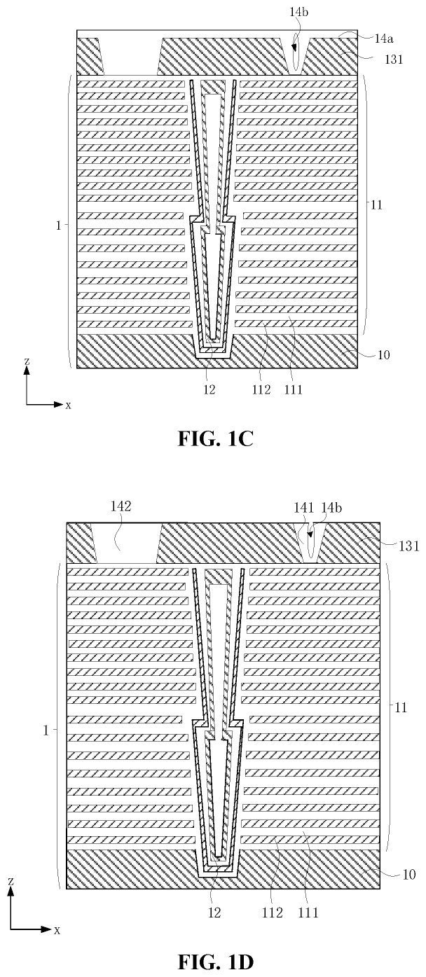

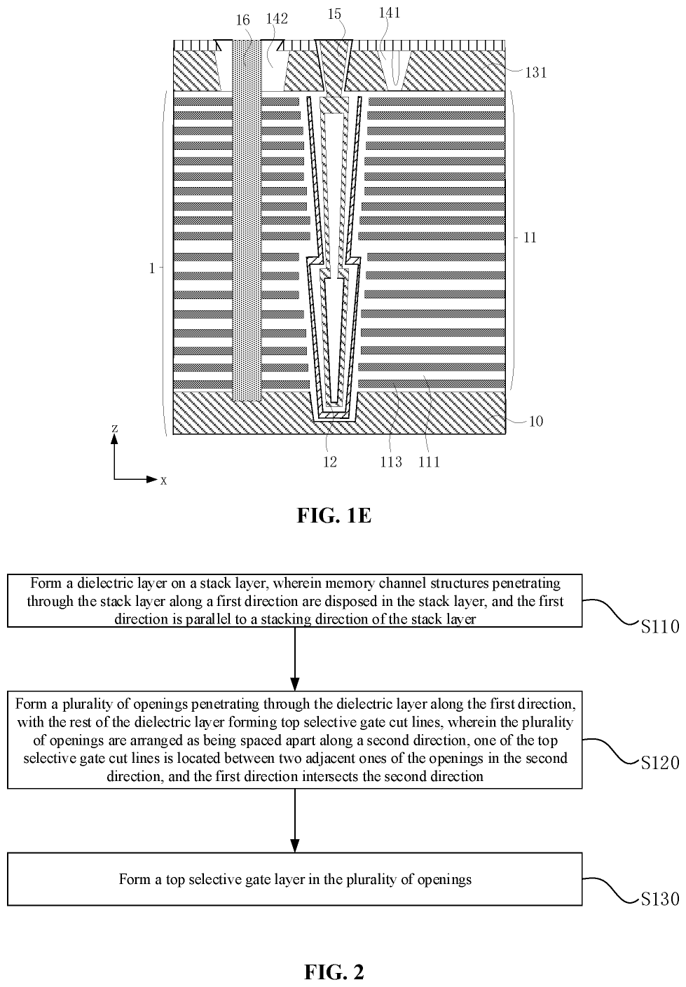

FIGS. 1A to 1E are schematic structure diagrams illustrating a manufacturing method of a semiconductor device according to some examples. Referring to FIGS. 1A to 1E, the manufacturing method of the semiconductor device at least comprises the following operations:

operation I: referring to FIG. 1A, providing a semiconductor structure 1 that comprises a semiconductor layer 10, a stack layer 11 and a memory channel structure 12, wherein the stack layer 11 is disposed on the semiconductor layer 10, the stack layer 11 comprises at least one gate dielectric layer 111 and at least one sacrificial layer 112 that are disposed alternately along a first direction z, and the memory channel structure 12 penetrates through the stack layer 11 and extends into the semiconductor layer 10 along the first direction z;

operation II: referring to both FIGS. 1A and 1B, forming an initial top selective gate layer 13 on a surface of the stack layer 11 far away from the semiconductor layer 10 in the first direction z, and forming a top selective gate cut 13a and a gate line slit top insulation portion opening 13b that penetrate through the initial top selective gate layer 13 along the first direction z, with the rest of the initial top selective gate layer 13 constituting a top selective gate layer 131, wherein the top selective gate cut 13a and the gate line slit top insulation portion opening 13b are disposed as being spaced apart along a second direction x perpendicular to the first direction z;

operation III: referring to FIGS. 1C and 1D, forming a dielectric layer 14a that fills the top selective gate cut 13a and the gate line slit top insulation portion opening 13b and covers a surface of the top selective gate layer 131 far away from the semiconductor layer 10, and then processing the dielectric layer 14a by using chemical mechanical polishing to remove the dielectric layer 14a outside the top selective gate cut 13a and the gate line slit top insulation portion opening 13b, with the rest of the dielectric layer 14a comprising a top selective gate cut line 141 and a gate line slit top insulation portion 142, wherein the top selective gate cut line 141 is located in the top selective gate cut 13a, and the gate line slit top insulation portion 142 is located in the gate line slit top insulation portion opening 13b;

operation IV: referring to FIG. 1E, forming a top selective channel hole penetrating through the top selective gate layer 131 and part of the gate dielectric layers 111 along the first direction z, wherein the top selective channel hole is disposed as being aligned with the memory channel structure 12, and a top selective channel structure 15 is formed in the top selective channel hole, and is connected with the memory channel structure 12; and

operation V: with continued reference to FIG. 1E, forming a gate line slit that penetrates through the gate line slit top insulation portion 142 and the stack layer 11 and extends into the semiconductor layer 10 along the first direction z, replacing at least one sacrificial layer 112 with at least one gate layer 113 through the gate line slit, and then forming a gate line slit structure 16 filling the gate line slit.

By performing the above operations, the top selective gate cut line 141, the gate line slit top insulation portion 142, the top selective channel structure 15 and the gate line slit structure 16 can be formed. A small quantity of air gaps 14b may appear in the top selective gate cut line 141.

FIG. 2 is a flow diagram of a manufacturing method of a semiconductor device of some examples of the present application. Referring to FIG. 2, the method comprises the following operations:

operation S110: forming a dielectric layer on a stack layer, wherein memory channel structures penetrating through the stack layer along a first direction are disposed in the stack layer, and the first direction is parallel to a stacking direction of the stack layer;

operation S120: forming a plurality of openings penetrating through the dielectric layer along the first direction, with the rest of the dielectric layer forming top selective gate cut lines, wherein the plurality of openings are arranged as being spaced apart along a second direction, one of the top selective gate cut lines is located between two adjacent ones of the openings in the second direction, and the first direction intersects the second direction; and operation S130: forming a top selective gate layer in the plurality of openings.

In some examples of the present application, first, the dielectric layer is formed, the plurality of openings penetrating through the dielectric layer are then formed along the first direction, with the rest of the dielectric layer forming the top selective gate cut lines, the plurality of openings are arranged as being spaced apart along the second direction, and then the top selective gate layer is formed in the plurality of openings. Since a process window of the plurality of openings is large, a process of fabricating the top selective gate cut lines is simplified to meet the process window requirements of the top selective gate cut lines, and the uniformity of sizes of the plurality of top selective gate cut lines is ensured. Moreover, the top selective gate cut lines are formed by forming the plurality of openings in the dielectric layer, thereby reducing air gaps inside the top selective gate cut lines, improving the problem that voltage breakdown appears for the top selective gate cut lines due to the presence of the air gaps, and improving the problem that the top selective gate cut lines are damaged by abrasive liquids due to the presence of the air gaps.

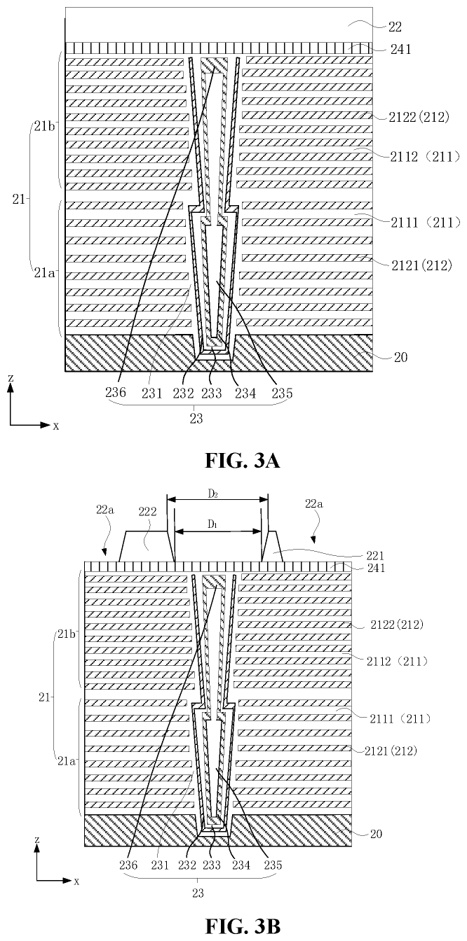

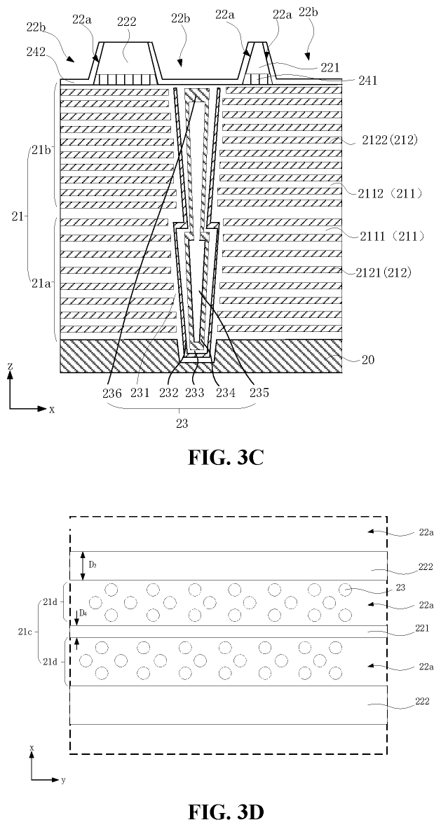

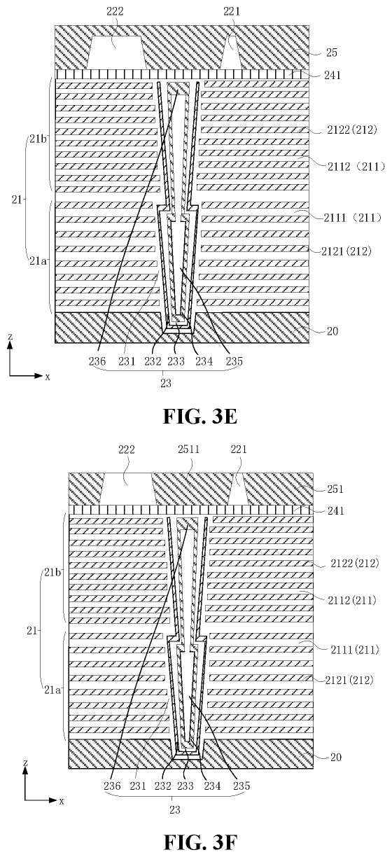

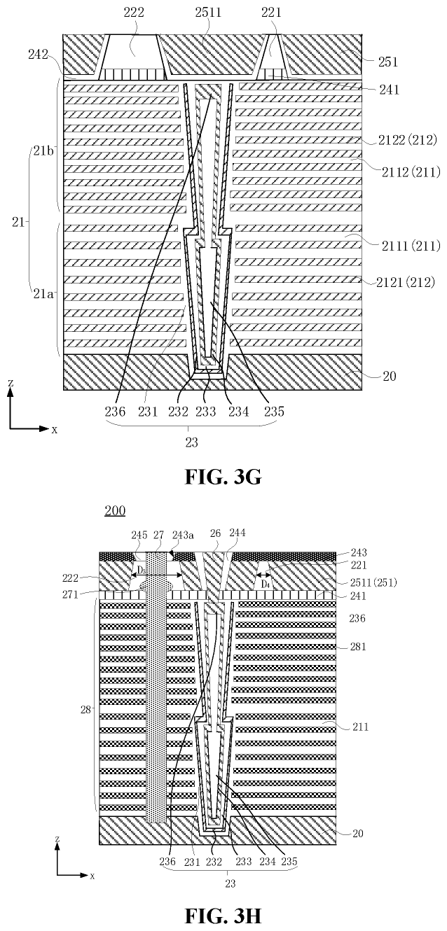

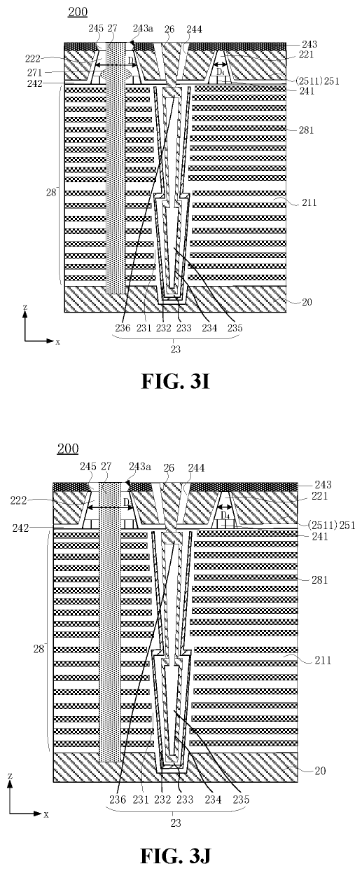

FIGS. 3A, 3B, 3D, 3E, 3F and 3H are schematic process diagrams of a manufacturing method of a semiconductor device of some examples of the present application, and FIGS. 3C, 3G, 3I and 3J are schematic process diagrams of a manufacturing method of a semiconductor device of some other examples of the present application. The present application will be illustrated below in more detail in conjunction with FIGS. 2 and 3A to 3J.

First, referring to FIG. 3A, operation S110 is performed: forming a dielectric layer 22 on a stack layer 21, wherein memory channel structures 23 penetrating through the stack layer 21 along the first direction z are disposed in the stack layer 21, and the first direction z is parallel to the stacking direction of the stack layer 21.

The stack layer 21 is disposed on a semiconductor layer 20. The material of the semiconductor layer 20 includes an elemental semiconductor material (e.g., silicon or polysilicon), a group III-V compound semiconductor material, a group II-VI compound semiconductor material, an organic semiconductor material or other semiconductor materials known in the art.

In an example, at least one gate dielectric layer 211 and at least one sacrificial layer 212 disposed alternately along the first direction z may be formed on the semiconductor layer 20 through a thin film deposition process to form the stack layer 21. The thin film deposition process includes, but is not limited to, a chemical vapor deposition (CVD) process, a plasma-enhanced chemical vapor deposition (PECVD) process, an atomic layer deposition (ALD) process or a combination thereof. The material of the gate dielectric layers 211 includes, but is not limited to, silicon oxide. The material of the sacrificial layers 212 includes, but is not limited to, silicon nitride.

In an example, forming at least one gate dielectric layer 211 and at least one sacrificial layer 212 disposed alternately along the first direction z on the semiconductor layer 20 comprises: forming at least one first gate dielectric layer 2111 and at least one first sacrificial layer 2121 disposed alternately on the semiconductor layer 20 to form a lower stack layer 21a; and forming at least one second gate dielectric layer 2112 and at least one second sacrificial layer 2122 disposed alternately on a side of the lower stack layer 21a far away from the semiconductor layer 20 to form an upper stack layer 21b.

Under the same etching condition, the first sacrificial layers 2121 and the second sacrificial layers 2122 may have high etching selectivity to the gate dielectric layers 211, such that the gate dielectric layers 211 are hardly removed when removing the first sacrificial layers 2121 and the second sacrificial layers 2122 in a subsequent process.

In an example, the material of the gate dielectric layers 211 includes an oxide. In an example, the material for the first gate dielectric layers 2111 and the second gate dielectric layers 2112 includes, for example, silicon oxide.

In an example, the material of the sacrificial layers 212 includes silicon nitride. In an example, the material for the first sacrificial layers 2121 includes, for example, silicon nitride, and the material for the second sacrificial layers 2122 includes, for example, dense silicon nitride.

In an example, the dielectric layer 22 may be formed on a side of the stack layer 21 far away from the semiconductor layer 20 through a thin film deposition process. The thin film deposition process includes, but is not limited to, a chemical vapor deposition process, a plasma-enhanced chemical vapor deposition process, an atomic layer deposition process or a combination thereof.

In an example, the material of the dielectric layer 22 includes, but is not limited to, an oxide, such as silicon oxide.

In some examples, before forming the dielectric layer 22 on the stack layer 21, the above method further comprises:

forming memory channel holes (not illustrated) that penetrate through the stack layer 21 and extend into the semiconductor layer 20; and forming the memory channel structures 23 in the memory channel holes.

In an example, forming the memory channel holes that penetrate through the stack layer 21 and extend into the semiconductor layer 20 comprises:

after forming the lower stack layer 21a, forming lower memory channel holes (not illustrated) that penetrate through the lower stack layer 21a and extend onto the semiconductor layer 20, and forming filling sacrificial layers (not illustrated) in the lower memory channel holes;

after forming the upper stack layer 21b, forming upper memory channel holes (not illustrated) that penetrate through the upper stack layer 21b and are disposed as being aligned with the lower memory channel holes, and forming filling sacrificial layers (not illustrated) in the upper memory channel holes; and

removing the filling sacrificial layers in the lower memory channel holes and the upper memory channel holes to form the memory channel holes (not illustrated).

In an example, forming the memory channel structures 23 in the memory channel holes comprises:

forming a barrier layer 231, a charge trapping layer 232, a tunneling layer 233 and a channel layer 234 in the memory channel holes sequentially. The channel layer 234 is configured to transport required charges (electrons or holes).

In an example, the barrier layer 231, the charge trapping layer 232 and the tunneling layer 233 may include a silicon oxide-silicon nitride-silicon oxide (ONO) structure. The material of the channel layer 234 includes polysilicon. A space inside the channel layer 234 is filled with a channel filling layer 235, and the material of the channel filling layer 235 includes, for example, silicon oxide or silicon oxynitride.

In an example, the barrier layer 231, the charge trapping layer 232 and the tunneling layer 233 may be deposited sequentially by using one or more thin film deposition processes (e.g., the processes such as ALD, CVD. PECVD or a combination thereof, etc.), and then, the channel layer 234 is formed on a side of the tunneling layer 233 far away from the barrier layer 231.

In an example, the memory channel structures 23 further comprise channel plugs 236 on a top of the channel filling layer 235 far away from the semiconductor layer 20, and the channel plugs 236 are in contact with the channel layer 234 to achieve electrical connection. The materials of the channel plugs 236 and the channel layer 234 are the same, such as polysilicon.

In an example, part of the top of the channel filling layer 235 far away from the semiconductor layer 20 may be processed through at least one of wet etching and dry etching, so as to form recesses on tops of the memory channel holes, and then, a semiconductor material such as polysilicon is deposited in the recesses through one or more thin film deposition processes (e.g., CVD, PECVD, ALD or a combination thereof) to form the channel plugs 236.

In some examples, before forming the dielectric layer 22 on the stack layer 21, the above method further comprises:

forming a first isolation layer 241 on the stack layer 21, wherein the material of the first isolation layer 241 is different from the material of the dielectric layer 22.

In some examples of the present application, the dielectric layer 22 is isolated from the stack layer 21 by the first isolation layer 241, so as to improve damages of an etching process to the memory channel structures 23 during subsequent etching processing for the dielectric layer 22. Moreover, the first isolation layer 241 can also have an effect of isolating the memory channel structures 23 from other conductive structures formed subsequently.

In an example, the first isolation layer 241 may be formed on a surface of the stack layer 21 far away from the semiconductor layer 20 by using a thin film deposition process. The thin film deposition process includes, but is not limited to, a chemical vapor deposition process, a plasma-enhanced chemical vapor deposition process, an atomic layer deposition process or a combination thereof.

In an example, the first isolation layer 241 includes, but is not limited to, at least one of a carbon-doped silicon nitride (NDC) layer, a silicon oxynitride layer, a silicon nitride layer, and a stack of a silicon oxide layer and a silicon nitride layer. In an example, the material of the first isolation layer 241 includes carbon-doped silicon nitride.

Next, referring to FIGS. 3B, 3C and 3D, operation S120 is performed to form the plurality of openings 22a penetrating through the dielectric layer 22 along the first direction z. with the rest of the dielectric layer forming the top selective gate cut lines 221, wherein the plurality of openings 22a are arranged as being spaced apart along the second direction x, one of the top selective gate cut lines 221 is located between two adjacent ones of the openings 22a in the second direction x, and the first direction z intersects the second direction x.

In some examples, referring to FIG. 3B, forming the plurality of openings 22a penetrating through the dielectric layer 22 along the first direction z comprises: forming the plurality of openings 22a penetrating through the dielectric layer 22 along the first direction z, wherein the plurality of openings 22a are disposed as being spaced apart along the second direction x.

In some examples of the present application, the plurality of openings 22a penetrate through the dielectric layer 22 instead of penetrating through the first isolation layer 241, thereby ensuring that the first isolation layer 241 has a protection effect on the memory channel structures 23 and the like, and improving the problem of a short circuit caused by contacting between the top selective gate layer subsequently formed in the openings 22a and the stack layer 21.

In some other examples, referring to FIG. 3C, forming the plurality of openings 22a penetrating through the dielectric layer 22 along the first direction z comprises: forming the plurality of openings 22a penetrating through the dielectric layer 22 and the first isolation layer 241 along the first direction z, wherein the plurality of openings 22a are disposed as being spaced apart along the second direction x.

In some other examples, with continued reference to FIG. 3C, after making the plurality of openings 22a penetrate through the first isolation layer 241, the above method further comprises:

forming a second isolation layer 242 at least on bottoms of the plurality of openings 22a, with unfilled portions of the openings 22a constituting grooves 22b.

In some other examples of the present application, the second isolation layer 242 is at least formed on the bottoms of the plurality of openings 22a, such that the stack layer 21 is insulated from the top selective gate layer to be subsequently formed in the plurality of openings 22a.

In some other examples, sizes of bottoms of the grooves 22b close to the stack layer 21 along the second direction x are smaller than sizes of tops of the grooves 22b far away from the stack layer 21 along the second direction x.

In an example, the shapes of cross-sections of the grooves 22b parallel to the first direction z and the second direction x are inverted trapezoids or are substantially inverted trapezoids.

In an example, referring to FIG. 3C, the second isolation layer 242 is located on the bottoms and sidewalls of the plurality of openings 22a, with the unfilled portions of the openings 22a constituting the grooves 22b. The second isolation layer 242 may also be located only on the bottoms of the plurality of openings 22a.

In some examples of the present application, the second isolation layer 242 on the sidewalls of the plurality of openings 22a can reduce the risk of a short circuit between top selective gates of the top selective gate layer subsequently formed in the plurality of openings 22a.

In an example, an initial second isolation layer (not illustrated) covering the bottoms of the plurality of openings 22a, the sidewalls of the plurality of openings 22a and a surface of the rest of the dielectric layer far away from the semiconductor layer 20 is formed using a thin film deposition process, and the initial second isolation layer outside the plurality of openings 22a is removed, with the rest of the initial second isolation layer constituting the second isolation layer 242. The thin film deposition process includes, but is not limited to, a chemical vapor deposition process, a plasma-enhanced chemical vapor deposition process, an atomic layer deposition process or a combination thereof. In an example, the second isolation layer 242 is formed using the atomic layer deposition process, such that the second isolation layer 242 has higher density, and can have a stronger effect of isolation.

In some other examples, a density of the second isolation layer 242 is greater than a density of the dielectric layer 22.

In some other examples, the material of the second isolation layer 242 is different from the material of the first isolation layer 241.

In an example, the material of the second isolation layer 242 includes, but is not limited to, carbon-doped silicon nitride, silicon oxynitride, silicon nitride and silicon oxide. In an example, the material of the second isolation layer 242 includes dense silicon oxide.

In some examples, referring to FIGS. 3B and 3C, sizes D1 of the bottoms of the openings 22a close to stack layer 21 in the second direction x are smaller than sizes D2 of the tops of the openings 22a far away from the stack layer 21 in the second direction x.

In an example, the shapes of cross-sections of the openings 22a parallel to the first direction z and the second direction x are inverted trapezoids or are substantially inverted trapezoids.

In an example, depths of the plurality of openings 22a are the same or substantially the same.

In an example, the first direction z is perpendicular to the second direction x. Referring to FIGS. 3B and 3C, the above method further comprises:

making the rest of the dielectric layer further form gate line slit top insulation portions 222, wherein one of the gate line slit top insulation portions 222 is located between two adjacent ones of the openings 22a in the second direction x, and the gate line slit top insulation portions 222 are spaced apart from the top selective gate cut lines 221 in the second direction x.

The openings 22a disposed as being spaced apart along the second direction x are formed in the dielectric layer 22, so as to form both the gate line slit top insulation portions 222 and the top selective gate cut lines 221. Since the process window of the plurality of openings 22a is large and the same or substantially the same, the difference in the sizes of the gate line slit top insulation portions 222 in different regions can be reduced, and the problem of mutual constraints between an etching window of top selective gate cuts with smaller sizes and an etching window of the gate line slit top insulation portion openings with larger sizes in some examples can also be improved while reducing the difference in the sizes of the top selective gate cut lines 221 in different regions.

Referring to FIG. 3D, a memory area of the stack layer 21 comprises a plurality of block memory areas 21c disposed along the second direction x, wherein each block memory area 21c comprises a plurality of finger memory areas 21d disposed as being spaced apart along the second direction x. Each of the finger memory areas 21d is provided with a plurality of the memory channel structures 23. Two adjacent ones of the finger memory areas 21d are spaced apart by one of the top selective gate cut lines 221. Each opening 22a is located in one of the finger memory areas 21d. Correspondingly, each opening 22a and the plurality of memory channel structures 23 of one of the finger memory areas 21d overlap.

In addition, the plurality of openings 22a, the top selective gate cut lines 221 and the gate line slit top insulation portions 222 all extend along a third direction y that intersects the second direction x. At least one top selective gate cut line 221 is disposed between two adjacent ones of the gate line slit top insulation portions 222.

In an example, the third direction y is perpendicular to the second direction x, and is perpendicular to the first direction z. It can be understood that, an included angle between the third direction y and the second direction x may also be an acute angle or a blunt angle.

In some examples, with continued reference to FIG. 3D, sizes D3 of the gate line slit top insulation portions 222 along the second direction x are greater than sizes D4 of the top selective gate cut lines 221 along the second direction x. In an example, the sizes D3 of the gate line slit top insulation portions 222 along the second direction x are in a scale of micrometers, and the sizes D4 of the top selective gate cut lines 221 along the second direction x are in a scale of nanometers.

It is to be noted that, the sizes D3 of the gate line slit top insulation portions 222 along the second direction x are greater than the sizes D4 of the top selective gate cut lines 221 along the second direction x, which means that the minimum value of the sizes D3 of the gate line slit top insulation portions 222 along the second direction x is greater than the maximum value of the sizes D4 of the top selective gate cut lines 221 along the second direction x.

In some examples, heights of the top selective gate cut lines 221 and heights of the gate line slit top insulation portions 222 are the same or substantially the same.

In some examples, in the case where the sizes DI of the bottoms of the openings 22a close to the stack layer 21 in the second direction x are smaller than the sizes D2 of the tops of the openings 22a far away from the stack layer 21 in the second direction x, since each of the top selective gate cut lines 221 is located between two of the openings 22a, sizes of bottoms of the top selective gate cut lines 221 close to the stack layer 21 in the second direction x are greater than sizes of tops of the top selective gate cut lines 221 far away from the stack layer 21 in the second direction x. Similarly, since each of the gate line slit top insulation portions 222 is located between two of the openings 22a, the sizes of the bottoms of the gate line slit top insulation portions 222 close to the stack layer 21 in the second direction x are greater than sizes of tops of the gate line slit top insulation portions 222 far away from the stack layer 21 in the second direction x.

In an example, the shapes of cross-sections of the top selective gate cut lines 221 parallel to the first direction z and the second direction x are trapezoids or are substantially trapezoids. At the same time, the shapes of cross-sections of the gate line slit top insulation portions 222 parallel to the first direction z and the second direction x also are trapezoids or are substantially trapezoids.

Finally, referring to FIGS. 3E, 3F and 3G, operation S130 is performed: forming the top selective gate layer 251 in the plurality of openings 22a.

In the present application, by first forming the dielectric layer, then etching out a damascene pattern of the top selective gate layer 251 and then depositing the top selective gate layer 251, a process flow of the dielectric layer without air gaps or with reduced air gaps is achieved.

In some examples, referring to FIGS. 3E and 3F, forming the top selective gate layer 251 in the plurality of openings 22a comprises:

forming an initial top selective gate layer 25 that fills the plurality of openings 22a and covers surfaces of the gate line slit top insulation portions 222 far away from the semiconductor layer 20 and surfaces of the top selective gate cut lines 221 far away from the semiconductor layer 20; and

planarizing the initial top selective gate layer 25 to remove the initial top selective gate layer 25 outside the plurality of openings 22a, such that the rest of the initial top selective gate layer forms the top selective gate layer 251, wherein a surface of the top selective gate layer 251 far away from the semiconductor layer 20 is flush with or substantially flush with the surfaces of the gate line slit top insulation portions 222 far away from the semiconductor layer 20.

In some other examples, referring to FIG. 3G, after forming the second isolation layer 242 as shown in FIG. 3C above, forming the top selective gate layer 251 in the plurality of openings 22a comprises:

forming an initial top selective gate layer which fills the plurality of grooves 22b and covers the second isolation layer 242 in the plurality of openings 22a, the surfaces of the gate line slit top insulation portions 222 far away from the semiconductor layer 20 and the surfaces of the top selective gate cut lines 221 far away from the semiconductor layer 20; and

planarizing the initial top selective gate layer to remove the initial top selective gate layer outside the plurality of grooves 22b, such that the rest of the initial top selective gate layer forms the top selective gate layer 251, wherein the surface of the top selective gate layer 251 far away from the semiconductor layer 20 is flush with or substantially flush with the surfaces of the gate line slit top insulation portions 222 far away from the semiconductor layer 20.

In an example, the initial top selective gate layer 25 is formed using a thin film deposition process. The thin film deposition process includes, but is not limited to, physical vapor deposition.

In an example, the planarization processing method includes, but is not limited to, chemical mechanical polishing and an etching process.

In an example, the material of the top selective gate layer 251 includes polysilicon, metal, doped silicon and a combination thereof, and the metal includes, but is not limited to, tungsten, cobalt, copper and nickel. In an example, the material of the top selective gate layer 251 includes polysilicon.

It is to be noted that, the top selective gate layer 251 comprises a plurality of top selective gates 2511 located in the plurality of openings 22a or in the plurality of grooves 22b, with one top selective gate 2511 being disposed in each opening 22a or each groove 22b. In the case where the sizes D1 of the bottoms of the openings 22a close to the stack layer 21 in the second direction x are smaller than the sizes D2 of the tops of the openings 22a far away from the stack layer 21 in the second direction x, or in the case where the sizes of the bottoms of the grooves 22b close to the stack layer 21 along the second direction x are smaller than the sizes of the tops of the grooves 22b far away from the stack layer 21 along the second direction x, a size of the bottom of each of the top selective gates 2511 close to the stack layer 21 in the second direction x is greater than a size of the top of each of the top selective gates 2511 far away from the stack layer 21 in the second direction x.

In an example, the shapes of cross-sections of the plurality of top selective gates 2511 parallel to the first direction z and the second direction x are inverted trapezoids or are substantially inverted trapezoids.

Referring to FIGS. 3H, 3I and 3J, the above method further comprises: forming a third isolation layer 243 on a side of the top selective gate layer 251 far away from the semiconductor layer 20, wherein the third isolation layer 243 covers the top selective gate layer 251, the top selective gate cut lines 221 and the gate line slit top insulation portions 222.

In an example, the third isolation layer 243 covering the top selective gate layer 251, the top selective gate cut lines 221 and the gate line slit top insulation portions 222 may be formed by a thin film deposition process. The thin film deposition process includes, but is not limited to, a chemical vapor deposition process, a plasma-enhanced chemical vapor deposition process, an atomic layer deposition process or a combination thereof.

In some examples, the material of the third isolation layer 243 is different from the material of the dielectric layer 22.

In an example, the material of the third isolation layer 243 includes, but is not limited to, silicon nitride, silicon oxide and silicon oxynitride.

In some examples, with continued reference to FIG. 3H, after forming the top selective gate layer 251 as shown in FIG. 3F above, the above method further comprises:

forming top selective channel holes that penetrate through the top selective gate layer 251 and the first isolation layer 241 along the first direction z and are disposed as corresponding to the memory channel structures 23; and

forming top selective channel structures 26 connected with the memory channel structures 23 in the top selective channel holes.

In an example, forming the top selective channel holes that penetrate through the top selective gate layer 251 and the first isolation layer 241 along the first direction z and are disposed as corresponding to the memory channel structures 23 comprises:

forming first top selective channel holes (not illustrated) penetrating through the third isolation layer 243 and the top selective gate layer 251 along the first direction z through first etching;

forming a fourth isolation layer 244 on sidewalls and bottoms of the first top selective channel holes; and

forming second top selective channel holes (not illustrated) that penetrate through the fourth isolation layer 244 and the first isolation layer 241 along the first direction z through second etching, and exposing ends of the memory channel structures 23 far away from the semiconductor layer 20.

In an example, forming the top selective channel structures 26 connected with the memory channel structures in the top selective channel holes comprises:

forming the top selective channel structures 26 in contact with the channel plugs 236 of the memory channel structures 23 in the first top selective channel holes and the second top selective channel holes.

In an example, the material of the fourth isolation layer 244 is the same as the material of the dielectric layer 22. The material of the fourth isolation layer 244 includes an oxide, such as silicon oxide.

In some other examples, referring to FIG. 3I, after forming the top selective gate layer 251 as shown in FIG. 3G above, the above method further comprises:

forming the top selective channel holes that penetrate through the top selective gate layer 251 and the second isolation layer 242 along the first direction z and are disposed as corresponding to the memory channel structures 23; and

forming the top selective channel structures 26 connected with the memory channel structures 23 in the top selective channel holes.

In an example, forming the top selective channel holes that penetrate through the top selective gate layer 251 and the second isolation layer 242 along the first direction z and are disposed as corresponding to the memory channel structures 23 comprises:

forming first top selective channel holes (not illustrated) penetrating through the third isolation layer 243 and the top selective gate layer 251 along the first direction z through first etching;

forming a fourth isolation layer 244 on sidewalls and bottoms of the first top selective channel holes; and

forming second top selective channel holes (not illustrated) that penetrate through the fourth isolation layer 244 and the second isolation layer 242 along the first direction z through second etching, and exposing ends of the memory channel structures 23 far away from the semiconductor layer 20.

In some examples, sizes of bottoms of the top selective channel structures 26 close to the semiconductor layer 20 along the second direction x are greater than sizes of tops of the top selective channel structures 26 far away from the semiconductor layer 20 along the second direction x.

In an example, the shapes of cross-sections of the top selective channel structures 26 parallel to the first direction z and the second direction x are inverted trapezoids or are substantially inverted trapezoids.

It is to be noted that, referring to FIGS. 3H, 3I and 3J, the shapes of cross-sections of the top selective gates 2511 parallel to the first direction z and the second direction x are inverted trapezoids or are substantially inverted trapezoids, the shapes of the cross-sections of the top selective channel structures 26 parallel to the first direction z and the second direction x are inverted trapezoids or are substantially inverted trapezoids, and the shapes of cross-sections of the top selective gate cut lines 221 parallel to the first direction z and the second direction x are trapezoids or are substantially trapezoids. Therefore, the sizes of the tops of the top selective channel structures 26 far away from the semiconductor layer 20 are larger, which is compatible with the larger sizes of the tops of the top selective gates 2511 far away from the semiconductor layer 20; the sizes of the tops of the top selective gate cut lines 221 far away from the semiconductor layer 20 are smaller, and the sizes of the bottoms of the top selective channel structures 26 close to the semiconductor layer 20 are smaller, which is compatible to the smaller sizes of the bottoms of the top selective gates 2511 close to the semiconductor layer 20; and the sizes of the bottoms of the top selective gate cut lines 221 close to the semiconductor layer 20 are larger, thereby increasing a process window between the top selective channel structures 26 and the top selective gate cut lines 141 and overcoming the problem that the process window between the top selective channel structures 15 and the top selective gate cut lines 141 is small in some of the above examples.

In some examples, the material of the top selective channel structures 26 includes, but is not limited to, polysilicon.

Referring to FIGS. 3H, 3I and 3J, the above method further comprises:

forming gate line slits penetrating through the gate line slit top insulation portions 222. the first isolation layer 241 and the stack layer 21 along the first direction z;

replacing at least one sacrificial layer 212 with at least one gate layer 281 through the gate line slits to form a memory stack layer 28, wherein the memory stack layer 28 comprises at least one gate layer 281 and at least one gate dielectric layer 211; and forming gate line slit structures 27 in the gate line slits.

In an example, forming the gate line slits penetrating through the gate line slit top insulation portions 222, the first isolation layer 241 and the stack layer 21 along the first direction z comprises:

forming isolation layer openings 243a penetrating through the third isolation layer 243 through a first etching process, wherein the isolation layer openings 243a are disposed as corresponding to the gate line slit top insulation portions 222;

forming a fifth isolation layer 245 in the isolation layer openings 243a, wherein the material of the fifth isolation layer 245 is different from the material of the third isolation layer 243; and

forming the gate line slits that penetrate through the fifth isolation layer 245, the gate line slit top insulation portions 222, the first isolation layer 241 and the stack layer 21 and extend into the semiconductor layer 20 through a second etching process.

In an example, the material of the fifth isolation layer 245 includes an insulation material, including, but not limited to, silicon nitride, silicon oxide and silicon oxynitride. In an example, the material of the fifth isolation layer 245 includes silicon oxide.

In an example, forming the gate line slit structures 27 in the gate line slits comprises: forming the gate line slit structures 27 in the gate line slits using a thin film deposition process. The thin film deposition process includes, but is not limited to, a chemical vapor deposition process, a plasma-enhanced chemical vapor deposition process, an atomic layer deposition process, physical deposition or a combination thereof.

In an example, the gate line slit structures 27 comprise insulation layers; or the gate line slit structures 27 may also comprise insulation layers and common source layers filled inside the insulation layers. The material of the insulation layers includes, but is not limited to, silicon oxide, silicon nitride and silicon oxynitride. The material of the common source layers includes, but is not limited to, polysilicon.

In an example, the material of the gate layers 281 includes a metal, including, but not limited to, tungsten, cobalt, copper and nickel.

In some examples, with continued reference to FIG. 3H, the gate line slit structures 27 further comprise gate line slit protrusion structures 271, wherein the gate line slit protrusion structures 271 are located on sidewalls of the gate line slit structures 27 extending along the first direction z and are embedded in at least one of the gate line slit top insulation portions 222 and the first isolation layer 241, and the gate line slit protrusion structures 271 protrude relative to portions of the sidewalls of the gate line slit structures 27 except the gate line slit protrusion structures 271. When the gate line slit protrusion structures 271 are only embedded in the gate line slit top insulation portions 222, the gate line slit protrusion structures 271 are disposed close to the first isolation layer 241. Alternatively, the gate line slit protrusion structures 271 may be also embedded in the gate line slit top insulation portions 222 and the first isolation layer 241 Alternatively, the gate line slit protrusion structures 271 may be also embedded in the first isolation layer 241.

It is to be noted that, the formation of the gate line slit protrusion structures 271 is related to the etching of the gate line slits.

In some other examples, referring to FIG. 3J, the sidewalls of the gate line slit structures 27 extending along the first direction z are flat or substantially flat. Correspondingly, there is no above-mentioned gate line slit protrusion structure 271 on the sidewalls of the gate line slit structures 27 extending along the first direction z.

Based on the fabrication method as described previously, the present application further provides a semiconductor device. Referring to FIGS. 3H, 3I and 3J, the semiconductor device 200 comprises a semiconductor layer 20, a memory stack layer 28, memory channel structures 23, a top selective gate layer 251, top selective gate cut lines 221, gate line slit top insulation portions 222, top selective channel structures 26 and gate line slit structures 27.

Referring to FIG. 3H, in some examples, the memory stack layer 28 is located on the semiconductor layer 20. The memory stack layer 28 comprises at least one gate layer 281 and at least one gate dielectric layer 211 disposed alternately along a first direction z.

In an example, the material of the semiconductor layer 20 includes an elemental semiconductor material (e.g., silicon or polysilicon), a group III-V compound semiconductor material, a group II-VI compound semiconductor material, an organic semiconductor material or other semiconductor materials known in the art.

In an example, the material of the gate layers 281 includes a metal, including, but not limited to, tungsten, cobalt, copper and nickel.

In an example, the material of the gate dielectric layers 211 includes, but is not limited to, silicon oxide.

In some examples, the memory channel structures 23 penetrate through the memory stack layer 28 along the first direction z and extend into the semiconductor layer 20. The memory channel structures 23 comprise a barrier layer 231, a charge trapping layer 232, a tunneling layer 233 and a channel layer 234 that are disposed sequentially from outside to inside, and a channel filling layer 235 is filled inside the channel layer 234. The memory channel structures 23 further comprise channel plugs 236 at tops far away from the semiconductor layer 20.

In some examples, the top selective gate layer 251 is disposed on a side of the memory stack layer 28 in the first direction z.

In an example, the material of the top selective gate layer 251 includes polysilicon, metal, doped silicon and a combination thereof, and the metal includes, but is not limited to, tungsten, cobalt, copper and nickel. In an example, the material of the top selective gate layer 251 includes polysilicon.

In some examples, the top selective gate layer 251 comprises a plurality of top selective gates 2511 disposed as being spaced apart along a second direction x. In the second direction x, two top selective gates 2511 are disposed on two opposite sides of one top selective gate 2511, and two top selective gates 2511 are disposed on two opposite sides of one gate line slit top insulation portion 222.

In some examples, a size of the bottom of each of the top selective gates 2511 close to the memory stack layer 28 in the second direction x is smaller than a size of the top of each of the top selective gates 2511 far away from the memory stack layer 28 in the second direction x.

In an example, the shapes of cross-sections of the plurality of top selective gates 2511 parallel to the first direction z and the second direction x are inverted trapezoids or are substantially inverted trapezoids, and the first direction z intersects the second direction x. In an example, the first direction z is perpendicular to the second direction x.

In some examples, the top selective gate cut lines 221 penetrate through at least part of the top selective gate layer 251 along the first direction z. Sizes of bottoms of the top selective gate cut lines 221 close to the memory stack layer 28 in the second direction x are greater than sizes of tops of the top selective gate cut lines 221 far away from the memory stack layer 28 in the second direction, and the first direction z intersects the second direction x.

As compared with some examples in which the sizes of the bottoms of the top selective gate cut lines close to the memory stack layer in the second direction x are smaller than the sizes of the tops of the top selective gate cut lines far away from the memory stack layer in the second direction x, in some examples of the present application, the sizes of the bottoms of the top selective gate cut lines 221 close to the memory stack layer 28 in the second direction x are greater than the sizes of the tops of the top selective gate cut lines 221 far away from the memory stack layer 28 in the second direction x, such that a process window between the top selective gate cut lines and the top selective channel structures can be increased.

In an example, the top selective gate cut lines 221 penetrate through the top selective gate layer 251 along the first direction z.

In an example, the shapes of cross-sections of the top selective gate cut lines 221 parallel to the first direction z and the second direction x are trapezoids or are substantially trapezoids.

It is to be noted that, when the shapes of cross-sections of the top selective gate cut lines 221 parallel to the first direction z and the second direction x are trapezoids or are substantially trapezoids, and the shapes of cross-sections of the top selective channel structures 26 parallel to the first direction z and the second direction x are inverted trapezoids or are substantially inverted trapezoids, the sizes of the tops of the top selective channel structures 26 far away from the semiconductor layer 20 are larger, the sizes of the tops of the top selective gate cut lines 221 far away from the semiconductor layer 20 are smaller, the sizes of the bottoms of the top selective channel structures 26 close to the semiconductor layer 20 are smaller, and the sizes of the bottoms of the top selective gate cut lines 221 close to the semiconductor layer 20 are larger, thereby increasing the process window between the top selective channel structures 26 and the top selective gate cut lines 221 and overcoming the problem that the process window between the top selective channel structure 15 and the top selective gate cut line 141 is small in the related art.

In an example, the material of the top selective gate cut lines 221 includes, but is not limited to, an oxide, such as silicon oxide.

In some examples, the gate line slit top insulation portions 222 penetrate through at least part of the top selective gate layer 251 along the first direction z. The gate line slit top insulation portions 222 and the top selective gate cut lines 221 are disposed as being spaced apart along the second direction x. In the second direction x, at least one of the top selective gate cut lines 221 is disposed between two adjacent ones of the gate line slit top insulation portions 222.

In an example, the gate line slit top insulation portions 222 penetrate through the top selective gate layer 251 along the first direction z.

In some examples, sizes of bottoms of the gate line slit top insulation portions 222 close to the memory stack layer 28 in the second direction x are greater than sizes of tops of the gate line slit top insulation portions 222 far away from the memory stack layer 28 in the second direction x.

In an example, the shapes of cross-sections of the gate line slit top insulation portions 222 parallel to the first direction z and the second direction x also are trapezoids or are substantially trapezoids.

It is to be noted that, unlike some examples in which the shapes of the cross-sections of the gate line slit top insulation portions parallel to the first direction z and the second direction x are inverted trapezoids or are substantially inverted trapezoids, the shapes of the cross-sections of the gate line slit top insulation portions 222 parallel to the first direction z and the second direction x also are trapezoids or are substantially trapezoids, and the shapes of the cross-sections of the top selective channel structures 26 parallel to the first direction z and the second direction x also are inverted trapezoids or are substantially inverted trapezoids, which can increase the process window between the gate line slit structures 27 and the top selective channel structures 26.

In some examples, the sizes D3 of the gate line slit top insulation portions 222 along the second direction x are greater than the sizes D4 of the top selective gate cut lines 221 along the second direction x.

In an example, the sizes D3 of the gate line slit top insulation portions 222 along the second direction x are in a scale of micrometers, and the sizes D4 of the top selective gate cut lines 221 along the second direction x are in a scale of nanometers.

It is to be noted that, the sizes D3 of the gate line slit top insulation portions 222 along the second direction x are greater than the sizes D4 of the top selective gate cut lines 221 along the second direction x, which means that the minimum value of the sizes D3 of the gate line slit top insulation portions 222 along the second direction x is greater than the maximum value of the sizes D4 of the top selective gate cut lines 221 along the second direction x.

In some examples, heights of the top selective gate cut lines 221 and heights of the gate line slit top insulation portions 222 are the same or substantially the same.

In some examples, the gate line slit top insulation portions 222 are disposed on the same layer as the top selective gate cut lines 221.

In some examples, the material of the gate line slit top insulation portions 222 is the same as the material of the top selective gate cut lines 221.

In an example, the material of the gate line slit top insulation portions 222 includes, but is not limited to, an oxide, such as silicon oxide.

In some examples, the semiconductor device 200 further comprises a first isolation layer 241, wherein at least part of the first isolation layer 241 is located between the top selective gate cut lines 221 as well as the gate line slit top insulation portions 222 and the memory stack layer 28 in the first direction z, and the material of the first isolation layer 241 is different from the material of the top selective gate cut lines 221.

In some examples, the first isolation layer 241 is further located between the top selective gate layer 251 and the memory stack layer 28.

In an example, the first isolation layer 241 includes, but is not limited to, a carbon-doped silicon nitride (NDC) layer, a silicon oxynitride layer, a silicon nitride layer, and a stack of a silicon oxide layer and a silicon nitride layer. In an example, the material of the first isolation layer 241 includes carbon-doped silicon nitride.

In some examples, the semiconductor device 200 further comprises a third isolation layer 243 located on a side of the top selective gate layer 251 far away from the memory stack layer 28.

In some examples, the material of the third isolation layer 243 is different from the material of the dielectric layer 22.

In an example, the material of the third isolation layer 243 includes, but is not limited to, silicon nitride, silicon oxide and silicon oxynitride.

In some examples, the top selective channel structures 26 penetrate through the top selective gate layer 251 and the first isolation layer 241 along the first direction z, and are connected with the memory channel structures 23.

In an example, referring to FIG. 3H, the top selective channel structures 26 penetrate through the third isolation layer 243, the top selective gate layer 251, the first isolation layer 241 and part of the gate dielectric layers 211 along the first direction z, and are in contact with the channel plugs 236 of the memory channel structures 23.

In some examples, sizes of bottoms of the top selective channel structures 26 close to the semiconductor layer 20 along the second direction x are greater than sizes of tops of the top selective channel structures 26 far away from the semiconductor layer 20 along the second direction x.

In an example, the shapes of cross-sections of the top selective channel structures 26 parallel to the first direction z and the second direction x are inverted trapezoids or are substantially inverted trapezoids.

In some examples, a fourth isolation layer 244 is further disposed between the top selective channel structures 26 and the top selective gates 2511. The fourth isolation layer 244 has an effect of isolating the top selective channel structures 26 from the top selective gates 2511.

In an example, the material of the fourth isolation layer 244 is the same as the material of the dielectric layer 22. The material of the fourth isolation layer 244 includes an oxide, such as silicon oxide.

In some examples, the semiconductor device 200 further comprises a fifth isolation layer 245 that penetrates through the third isolation layer 243 along the first direction z and is located on surfaces of the gate line slit top insulation portions 222 far away from the semiconductor layer 20.

In some examples, the material of the fifth isolation layer 245 is different from the material of the third isolation layer 243.

In some examples, the material of the fifth isolation layer 245 is the same as the material of the dielectric layer 22.

In an example, the material of the fifth isolation layer 245 includes an oxide, such as silicon oxide.

In some examples, the gate line slit structures 27 penetrate through the gate line slit top insulation portions 222, the first isolation layer 241 and the memory stack layer 28 along the first direction z, and extend into the semiconductor layer 20.

In an example, the gate line slit structures 27 penetrate through the fifth isolation layer 245, the gate line slit top insulation portions 222, the first isolation layer 241 and the memory stack layer 28 along the first direction z, and extend into the semiconductor layer 20.

In an example, the gate line slit structures 27 comprise insulation layers; or the gate line slit structures 27 may also comprise insulation layers and common source layers filled inside the insulation layers. The material of the insulation layers includes, but is not limited to, silicon oxide, silicon nitride and silicon oxynitride, and the material of the common source layers includes, but is not limited to, polysilicon.

In some examples, the gate line slit structures 27 further comprise gate line slit protrusion structures 271, wherein the gate line slit protrusion structures 271 are located on sidewalls of the gate line slit structures 27 extending along the first direction z and are embedded in at least one of the gate line slit top insulation portions 222 and the first isolation layer 241, and the gate line slit protrusion structures 271 protrude relative to portions of the sidewalls of the gate line slit structures 27 except the gate line slit protrusion structures 271. In some other examples, referring to FIG. 3I, the top selective gate layer 251 further penetrates through the first isolation layer 241, the semiconductor device 200 further comprises a second isolation layer 242, and at least part of the second isolation layer 242 is located between the top selective gate layer 251 and the memory stack layer 28.

In an example, the second isolation layer 242 is disposed between sidewalls of the top selective gates 2511 and sidewalls of the gate line slit top insulation portions 222, between the sidewalls of the top selective gates 2511 and sidewalls of the top selective gate cut lines 221, and between the top selective gates 2511 and the memory stack layer 28.

In some other examples, a density of the second isolation layer 242 is greater than a density of the dielectric layer 22.

In some other examples, the material of the second isolation layer 242 is different from the material of the first isolation layer 241.

In an example, the material of the second isolation layer 242 includes, but is not limited to, carbon-doped silicon nitride, silicon oxynitride, silicon nitride and silicon oxide. In an example, the material of the second isolation layer 242 includes dense silicon oxide.

In some other examples, with continued reference to FIG. 3I, the top selective channel structures 26 penetrate through the top selective gate layer 251 and the second isolation layer 242 along the first direction z, and are connected with the memory channel structures 23.

In an example, the top selective channel structures 26 penetrate through the third isolation layer 243, the top selective gate layer 251, the second isolation layer 242 and part of the gate dielectric layers 211 along the first direction z, and are in contact with the channel plugs 236 of the memory channel structures 23.

In some other examples, referring to FIG. 3H, the sidewalls of the gate line slit structures 27 extending along the first direction z are flat or substantially flat. Correspondingly, there is no above-mentioned gate line slit protrusion structure 271 on the sidewalls of the gate line slit structures 27 extending along the first direction z.

Referring to FIG. 4, the present application further provides a memory 300 which is configured to store data. The memory 300 comprises a memory array 301 and a peripheral circuit 302, wherein the memory array 301 and the peripheral circuit 302 are stacked together, and the memory array 301 is connected with the peripheral circuit 302 and comprises the above-mentioned semiconductor device 200.

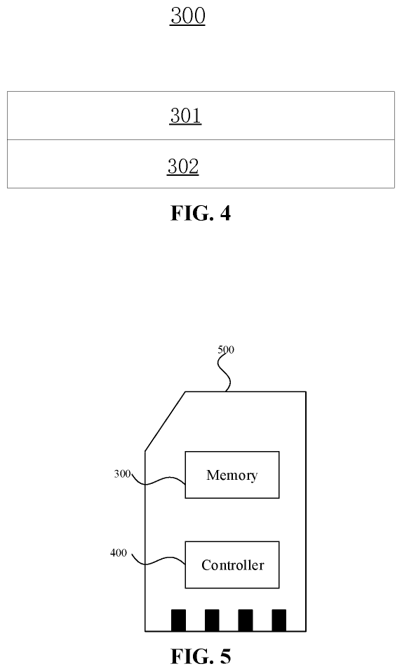

Referring to FIGS. 5 and 6, the present application further provides a memory system 500 which comprises a memory 300 and a controller 400, wherein the controller 400 is connected with the memory 300 and configured to control the memory 300 to store data.

The memory system 500 may be applied to and packaged into various types of electronic products, for example, a mobile phone (e.g. a cell phone), a desktop computer, a tablet computer, a notebook computer, a server, a vehicle apparatus, a gaming console, a printer, a positioning apparatus, a wearable apparatus, a smart sensor, a mobile power supply, a virtual reality (VR) apparatus, an augmented reality (AR) apparatus, or any other suitable electronic apparatuses having memories therein.

In some examples, referring to FIG. 5, the memory system 500 comprises one memory 300 and the controller 400. The memory system 500 may be integrated in a three-dimensional memory card.

The three-dimensional memory card includes any one of a PC (PCMCIA, Personal Computer Memory Card International Association) card, a Compact Flash (CF) card, a Smart Media (SM) card, a three-dimensional memory, a Multimedia Card (MMC), a Secure Digital Memory Card (SD) card, and a UFS.

In some other examples, referring to FIG. 6, the memory system 500 comprises a plurality of memories 300 and the controller 400. The memory system 500 is integrated into a solid state drive (SSD).

In some examples, in the memory system 500, the controller 400 is configured for operating in a low duty-cycle environment, such as Secure Digital (SD) cards, Compact Flash (CF) cards, Universal Serial Bus (USB) flash drives, or other media for use in electronic apparatuses, such as personal computers, digital cameras, mobile phones, etc.

In some other examples, in the memory system 500, the controller 400 is configured for operating in high duty-cycle environment like SSDs or eMMCs used as data memories for mobile apparatuses, such as smartphones, tablet computers, notebook computers, etc., and enterprise memory arrays.

In some examples, the controller 400 may be configured to manage the data stored in the memories 300 and communicate with an external apparatus (e.g., a host). In some examples, the controller 400 may be further configured to control operations of the memories 300, such as reading, erasing, and programming operations. In some examples, the controller 400 may be further configured to manage various functions with respect to data stored or to be stored in the memories 300, including at least one of bad-block management, garbage collection, logical-to-physical address conversion, and wear leveling. In some examples, the controller 400 is further configured to process error correction codes with respect to the data read from or written to the memories 300.

Of course, the controller 400 may also perform any other suitable functions, such as formatting the memories 300. For example, the controller 400 may communicate with an external apparatus (e.g., a host) through at least one of various interface protocols.

It is to be noted that, the interface protocols include at least one of a USB protocol, an MMC protocol, a Peripheral Component Interconnection (PCI) protocol, a PCI-Express (PCI-E) protocol, an Advanced Technology Attachment (ATA) protocol, a Serial-ATA protocol, a Parallel-ATA protocol, a Small Computer Small Interface (SCSI) protocol, an Enhanced Small Disk Interface (ESDI) protocol, an Integrated Drive Electronics (IDE) protocol and a Firewire protocol.

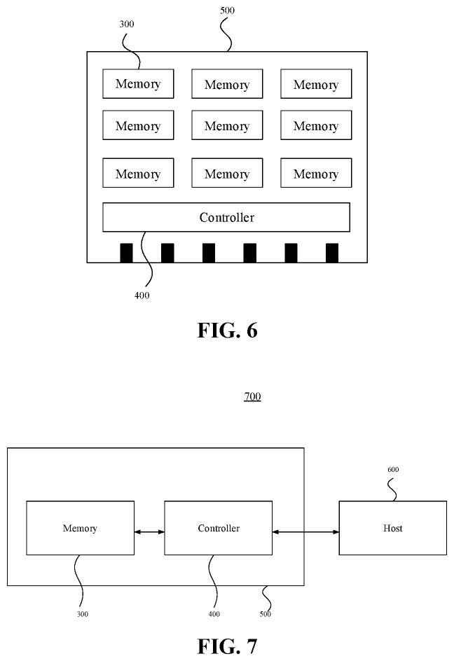

Referring to FIG. 7, the present application further discloses an electronic apparatus 700. The electronic apparatus 700 may be any one of a cell phone, a desktop computer, a tablet computer, a notebook computer, a server, a vehicle apparatus, a wearable apparatus (e.g., a smart watch, a smart bracelet, smart glasses, etc.), a mobile power supply, a gaming machine, a digital multimedia player, etc.

The electronic apparatus 700 may comprise the above-mentioned memory system 500 and a host 600, wherein the memory system 500 is connected with the host 600, and the host 600 comprises at least one of a central processing unit (CPU) and a cache, etc.

An example semiconductor device and an example manufacturing method thereof and an example memory system are disclosed. Some example implementations reduce manufacturing process difficulty of the semiconductor device and improve performance of the semiconductor device and the memory system.

In a first aspect, the present application provides a manufacturing method of a semiconductor device, which comprises: forming a dielectric layer on a stack layer, wherein memory channel structures penetrating through the stack layer along a first direction are disposed in the stack layer, and the first direction is parallel to a stacking direction of the stack layer; forming a plurality of openings penetrating through the dielectric layer along the first direction, with the rest of the dielectric layer forming top selective gate cut lines, wherein the plurality of openings are arranged as being spaced apart along a second direction, one of the top selective gate cut lines is located between two adjacent ones of the openings in the second direction, and the first direction intersects the second direction; and forming a top selective gate layer in the plurality of openings.

In some examples, area sizes of cross-sections of bottoms of the openings close to the stack layer in the second direction are smaller than area sizes of cross-sections of tops of the openings far away from the stack layer in the second direction.

In some examples, the method further comprises: making the rest of the dielectric layer form gate line slit top insulation portions, wherein one of the gate line slit top insulation portions is located between two adjacent ones of the openings in the second direction, and the gate line slit top insulation portions and the top selective gate cut lines are disposed as being spaced apart in the second direction.

In some examples, sizes of the gate line slit top insulation portions along the second direction are greater than sizes of the top selective gate cut lines along the second direction.

In some examples, before the forming the dielectric layer on the stack layer, the method further comprises: forming a first isolation layer on the stack layer, a material of the first isolation layer being different from a material of the dielectric layer.

In some examples, the method further comprises: forming gate line slits that penetrate through the gate line slit top insulation portions, the first isolation layer and the stack layer along the first direction; and forming gate line slit structures in the gate line slits.

In some examples, the method further comprises: making the plurality of openings penetrate through the first isolation layer.

In some examples, after making the plurality of openings penetrate through the first isolation layer, and before forming the top selective gate layer in the plurality of openings, the method further comprises: forming a second isolation layer at least on bottoms of the plurality of openings.

In some examples, the method further comprises: forming top selective channel holes that penetrate through the top selective gate layer and the second isolation layer along the first direction and are disposed as corresponding to the memory channel structures; and forming top selective channel structures connected with the memory channel structures in the top selective channel holes.

In some examples, before the forming the dielectric layer on the stack layer, the method further comprises: forming top selective channel holes that penetrate through the top selective gate layer and the first isolation layer along the first direction and are disposed as corresponding to the memory channel structures; and forming top selective channel structures connected with the memory channel structures in the top selective channel holes.

In a second aspect, the present application provides a semiconductor device comprising: a memory stack layer that comprises at least one gate layer and at least one gate dielectric layer disposed alternately along a first direction; memory channel structures penetrating through the memory stack layer along the first direction; a top selective gate layer disposed on a side of the memory stack layer in the first direction; and top selective gate cut lines penetrating through at least part of the top selective gate layer along the first direction, wherein sizes of bottoms of the top selective gate cut lines close to the memory stack layer in a second direction are greater than sizes of tops of the top selective gate cut lines far away from the memory stack layer in the second direction, and the first direction intersects the second direction.

In some examples, the semiconductor device further comprises: gate line slit top insulation portions penetrating through at least part of the top selective gate layer along the first direction, wherein the gate line slit top insulation portions and the top selective gate cut lines are disposed as being spaced apart along the second direction, and sizes of bottoms of the gate line slit top insulation portions close to the memory stack layer in the second direction are greater than sizes of tops of the gate line slit top insulation portions far away from the memory stack layer in the second direction.

In some examples, sizes of the gate line slit top insulation portions along the second direction are greater than sizes of the top selective gate cut lines along the second direction.

In some examples, the semiconductor device further comprises: a first isolation layer, wherein at least part of the first isolation layer is located between the top selective gate cut lines as well as the gate line slit top insulation portions and the memory stack layer in the first direction, and a material of the first isolation layer is different from a material of the top selective gate cut lines.

In some examples, the first isolation layer is further located between the top selective gate layer and the memory stack layer; and the semiconductor device further comprises: top selective channel structures that penetrate through the top selective gate layer and the first isolation layer along the first direction and are connected with the memory channel structures.

In some examples, the top selective gate layer further penetrates through the first isolation layer; and the semiconductor device further comprises a second isolation layer, wherein at least part of the second isolation layer is located between the top selective gate layer and the memory stack layer.

In some examples, the semiconductor device further comprises: top selective channel structures that penetrate through the top selective gate layer and the second isolation layer along the first direction and are connected with the memory channel structures.

In some examples, the semiconductor device further comprises: gate line slit structures penetrating through the gate line slit top insulation portions, the first isolation layer and the memory stack layer along the first direction.

In some examples, the first isolation layer includes at least one of a carbon-doped silicon nitride layer, a silicon oxynitride layer, a silicon nitride layer, and a stack of a silicon oxide layer and a silicon nitride layer.

In a third aspect, the present application provides a memory system comprising: a memory comprising the semiconductor device of any of the examples above; and a controller connected with the memory and configured to control the memory.

In some examples of the present application, the dielectric layer is formed on the stack layer provided with the memory channel structures, the plurality of openings penetrating through the dielectric layer along the first direction are then formed, with the rest of the dielectric layer forming the top selective gate cut lines, the plurality of openings are arranged as being spaced apart along the second direction, and the top selective gate layer is formed in the plurality of openings. In the manufacturing method of the semiconductor device, since process windows of the plurality of openings are the same, the process difficulty of manufacturing the top selective gate cut lines can be reduced; at the same time, the size uniformity of the top selective gate cut lines can be improved, and the problem of mutual constraints between the process windows caused by large differences in the sizes of the top selective gate cut lines and the gate line slit top insulation portions in the related art can be improved. Moreover, the rest of the dielectric layer forms the top selective gate cut lines, such that the problem that air gaps appear inside the top selective gate cut lines can be relieved, thereby relieving the problem that voltage breakdown appears for the top selective gate cut lines due to the presence of the air gaps, and relieving damages to the top selective gate cut lines into which abrasive liquids used in chemical mechanical polishing flows due to the presence of the air gaps.

In addition, since the sizes of the bottoms of the top selective gate cut lines close to the memory stack layer in the second direction are greater than the sizes of the tops of the top selective gate cut lines far away from the semiconductor layer in the second direction, the process window between the top selective gate cut lines and the top selective channel structures is increased.

The descriptions of the above examples are only to help understand technical solutions and core ideas of the present application. Those of ordinary skill in the art should understand that they may still modify the technical solutions as set forth in various aforementioned examples, or equivalently substitute part of the technical features. However, these modifications or substitutions do not make the essence of the respective technical solutions depart from the scope of the technical solutions of various examples of the present application.

What is claimed is:

1. A manufacturing method of a semiconductor device, the manufacturing method comprising:
forming a dielectric layer on a stack layer, wherein memory channel structures penetrating through the stack layer along a first direction are disposed in the stack layer, and the first direction is parallel to a stacking direction of the stack layer;
forming a plurality of openings penetrating through the dielectric layer along the first direction, with the rest of the dielectric layer forming top selective gate cut lines, wherein the plurality of openings are arranged as being spaced apart along a second direction, one of the top selective gate cut lines is located between two adjacent ones of the openings in the second direction, and the first direction intersects the second direction; and
forming a top selective gate layer in the plurality of openings.

2. The manufacturing method of the semiconductor device of claim 1, wherein sizes of bottoms of the openings close to the stack layer in the second direction are smaller than sizes of tops of the openings far away from the stack layer in the second direction.

3. The manufacturing method of the semiconductor device of claim 1, further comprising:
making the rest of the dielectric layer form gate line slit top insulation portions, wherein one of the gate line slit top insulation portions is located between two adjacent ones of the openings in the second direction, and the gate line slit top insulation portions and the top selective gate cut lines are disposed as being spaced apart in the second direction.

4. The manufacturing method of the semiconductor device of claim 3, wherein sizes of the gate line slit top insulation portions along the second direction are greater than sizes of the top selective gate cut lines along the second direction.

5. The manufacturing method of the semiconductor device of claim 3, wherein, before the forming the dielectric layer on the stack layer, the method further comprises:
forming a first isolation layer on the stack layer, a material of the first isolation layer being different from a material of the dielectric layer.

6. The manufacturing method of the semiconductor device of claim 5, further comprising:
forming gate line slits that penetrate through the gate line slit top insulation portions, the first isolation layer and the stack layer along the first direction; and
forming gate line slit structures in the gate line slits.

7. The manufacturing method of the semiconductor device of claim 5, further comprising:
making the plurality of openings penetrate through the first isolation layer.

8. The manufacturing method of the semiconductor device of claim 7, wherein, after making the plurality of openings penetrate through the first isolation layer, and before forming the top selective gate layer in the plurality of openings, the method further comprises:
forming a second isolation layer at least on bottoms of the plurality of openings.

9. The manufacturing method of the semiconductor device of claim 8, further comprising:
forming top selective channel holes that penetrate through the top selective gate layer and the second isolation layer along the first direction and are disposed as corresponding to the memory channel structures; and
forming top selective channel structures connected with the memory channel structures in the top selective channel holes.

10. The manufacturing method of the semiconductor device of claim 5, further comprising:
forming top selective channel holes that penetrate through the top selective gate layer and the first isolation layer along the first direction and are disposed as corresponding to the memory channel structures; and
forming top selective channel structures connected with the memory channel structures in the top selective channel holes.

11. A semiconductor device, comprising:
a memory stack layer that comprises at least one gate layer and at least one gate dielectric layer disposed alternately along a first direction;
memory channel structures penetrating through the memory stack layer along the first direction;
a top selective gate layer disposed on a side of the memory stack layer in the first direction; and
top selective gate cut lines penetrating through at least part of the top selective gate layer along the first direction, wherein sizes of bottoms of the top selective gate cut lines close to the memory stack layer in a second direction are greater than sizes of tops of the top selective gate cut lines far away from the memory stack layer in the second direction, and the first direction intersects the second direction.

12. The semiconductor device of claim 11, further comprising:
gate line slit top insulation portions penetrating through at least part of the top selective gate layer along the first direction, wherein the gate line slit top insulation portions and the top selective gate cut lines are disposed as being spaced apart along the second direction, and sizes of bottoms of the gate line slit top insulation portions close to the memory stack layer in the second direction are greater than sizes of tops of the gate line slit top insulation portions far away from the memory stack layer in the second direction.

13. The semiconductor device of claim 12, wherein sizes of the gate line slit top insulation portions along the second direction are greater than sizes of the top selective gate cut lines along the second direction.

14. The semiconductor device of claim 12, further comprising:
a first isolation layer, wherein at least part of the first isolation layer is located between the top selective gate cut lines as well as the gate line slit top insulation portions and the memory stack layer in the first direction, and a material of the first isolation layer is different from a material of the top selective gate cut lines.

15. The semiconductor device of claim 14, wherein the first isolation layer is further located between the top selective gate layer and the memory stack layer; and
the semiconductor device further comprises: top selective channel structures that penetrate through the top selective gate layer and the first isolation layer along the first direction and are connected with the memory channel structures.

16. The semiconductor device of claim 14, wherein the top selective gate layer further penetrates through the first isolation layer; and
the semiconductor device further comprises a second isolation layer, wherein at least part of the second isolation layer is located between the top selective gate layer and the memory stack layer.

17. The semiconductor device of claim 16, further comprising:
top selective channel structures that penetrate through the top selective gate layer and the second isolation layer along the first direction and are connected with the memory channel structures.

18. The semiconductor device of claim 14, further comprising:
gate line slit structures penetrating through the gate line slit top insulation portions, the first isolation layer and the memory stack layer along the first direction.

19. The semiconductor device of claim 14, wherein the first isolation layer includes at least one of a carbon-doped silicon nitride layer, a silicon oxynitride layer, a silicon nitride layer, and a stack of a silicon oxide layer and a silicon nitride layer.

20. A memory system, comprising:
a memory comprising:
a semiconductor device, comprising:
a memory stack layer that comprises at least one gate layer and at least one gate dielectric layer disposed alternately along a first direction;
memory channel structures penetrating through the memory stack layer along the first direction;
a top selective gate layer disposed on a side of the memory stack layer in the first direction; and
top selective gate cut lines penetrating through at least part of the top selective gate layer along the first direction, wherein sizes of bottoms of the top selective gate cut lines close to the memory stack layer in a second direction are greater than sizes of tops of the top selective gate cut lines far away from the memory stack layer in the second direction, and the first direction intersects the second direction, and
a controller connected with the memory and configured to control the memory.
